(19) United States
(12) Patent Application Publication
(10) Pub. No.: US 2026/0277361 A1
(43) Pub. Date: Sep. 17, 2026

(54) DISPLAY DEVICE INCLUDING A TOUCH SENSING UNIT AND ELECTRONIC DEVICE USING THE SAME

(71) Applicant: SAMSUNG DISPLAY CO., LTD., YONGIN-SI (KR)

(72) Inventors: Tae Kwang KIM, Yongin-si (KR); Kyu Bong JUNG, Yongin-si (KR)

(21) Appl. No.: 19/358,839

(22) Filed: Oct. 15, 2025

(30) Foreign Application Priority Data
Mar. 13, 2025 (KR) 10-2025-0032538

(51) Int. Cl. G06F 3/041; H10K 59/40; G09G 3/20

(52) U.S. Cl. CPC G06F 3/0418; G06F 3/0412; H10K 59/40; G06F 2203/04107; G09G 3/2092; G09G 2330/021; G09G 2330/06; G09G 2354/00

(57) ABSTRACT

A display panel displays an image through pixels of a display area. A touch driving circuit detects a touch through a touch sensing unit of the display panel and generates touch coordinate data therefrom. A display driving circuit supplies a data voltage to the pixels of the display area and controls an image display timing of the pixels. A circuit board includes touch lines, ground lines, interface lines, power lines, and option control lines and is electrically in contact with the display panel. A low-resistance film covers an upper surface of the circuit board. The low-resistance film is disposed on an upper surface of the interface lines and corresponds to the interface lines.

### CROSS-REFERENCE TO RELATED APPLICATION

This application claims priority under 35 U.S.C. §119 to Korean Patent Application No. 10-2025-0032538, filed on Mar. 13, 2025 in the Korean Intellectual Property Office, the contents of which are herein incorporated by reference in its entirety.

### TECHNICAL FIELD

The present disclosure relates to a display device and, more specifically, to a display device including a touch sensing unit and an electronic device using the same.

### DISCUSSION OF THE RELATED ART

As technology has advanced, the demand for display devices in a wide variety of forms has steadily increased. For example, display devices have been applied to various electronic devices such as smart phones, digital cameras, laptop/notebook computers, navigation devices, and smart televisions.

The display device may be a flat panel display device such as a liquid crystal display device, a field emission display device and an organic light emitting display device. The light emitting display device of the flat panel display device may include a light emitting element in which each of pixels of a display panel may self-emit light, thereby displaying an image even without the need for a backlight unit that provides light to the display panel.

The display device controls a driving timing (e.g., an image display timing) of the display panel to be synchronized with synchronous signals such as an enable signal and a frequency clock from a graphic system such as a graphic card or a built-in graphic control processor (e.g., a microprocessor). The display device may perform bidirectional communication with an external graphic system or the built-in graphic control processor in an interface communication manner such as Mobile Industry Processor Interface (MIPI).

### SUMMARY

A display device includes a display panel including a plurality of pixels disposed within a display area of the display panel. A touch driving circuit includes a touch sensing unit disposed within the display panel. The touch sensing unit is configured to generate touch coordinate data. A display driving circuit is configured to supply a data voltage to the plurality of pixels of the display area and control an image display timing of the plurality of pixels. A circuit board includes touch lines, ground lines, interface lines, power lines, and option control lines. The circuit board is electrically connected to the display panel. A low-resistance film is disposed on an upper surface of the circuit board. The low-resistance film is disposed on an upper surface of the interface lines.

Each of the touch lines, the ground lines, the interface lines, the power lines, and the option control lines may be stacked in a plurality of layers with interlayer insulating layers interposed therebetween. The low-resistance film may be disposed on the upper surface of the interface lines, and may include an impedance control pattern area having a shape of at least one opening or at least one cutout.

The low-resistance film may include a rubber material, a non-conductive film including a non-conductive ceramic compound, an insulating tape including a non-conductive thin film forming material, or an insulating plastic film.

The circuit board may include a main plane area including an element arrangement area, an output pad area, and a line-embedded area and a sub-extension area protruding and extending from the main plane area and including an input pad area including a plurality of input pads. The low-resistance film may at least partially cover a front surface of the line-embedded area and a front surface of the sub-extension area.

Each of the touch lines, the ground lines, the interface lines, the power lines, and the option control lines may be stacked on different layers with various interlayer insulating layers interposed therebetween. The low-resistance film may be disposed in front of the interface lines.

The low-resistance film may include an impedance control pattern area having a shape of at least one opening or at least one cutout corresponding to the upper surface of the interface lines. The impedance control pattern area may overlap the interface lines and may be configured to adjust or maintain impedance sizes and electromagnetic interference magnitudes of the interface lines formed in the main plane area or the sub-extension area.

The circuit board may include a base substrate and a touch line layer disposed on the base substrate, including touch lines and at least one first interlayer insulating layer. A first ground line layer may be disposed on the touch line layer and may include first ground lines and at least one second interlayer insulating layer. An interface line layer may be disposed on the first ground line layer and may include interface lines and at least one third interlayer insulating layer. A second ground line layer may be disposed on the interface line layer and may include second ground lines and at least one fourth interlayer insulating layer. An option control line layer may be disposed on the second ground line layer and may include option control lines and at least one fifth interlayer insulating layer.

The low-resistance film may be disposed in front of the interface lines and may correspond to the interface lines. The low-resistance film may include an impedance control pattern area having a shape of at least one opening or at least one cutout to correspond to the upper surface of the interface lines.

A display device includes a display panel including pixels disposed in a display area thereof. A touch driving circuit includes a touch sensing unit disposed within the display panel, the touch sensing unit being configured to generate touch coordinate data. A display driving circuit is configured to supply a data voltage to the plurality of pixels of the display area and control an image display timing of the plurality of pixels. A circuit board includes touch lines, ground lines, interface lines, power lines, and option control lines. The circuit board is electrically connected to the display panel. The circuit board includes a low-resistance film disposed on an upper surface of the circuit board. The low-resistance film is arranged on an upper surface of the interface lines.

The low-resistance film may include a rubber, a non-conductive film including a non-conductive ceramic compound, an insulating tape including a non-conductive thin film forming material, or an insulating plastic film.

The circuit board may include a main plane area including an element arrangement area, an output pad area, and a line-embedded area, and a sub-extension area protruding and extending from the main plane area and including an input pad area including a plurality of input pads. The low-resistance film may at least partially cover a front surface of the line-embedded area and a front surface of the sub-extension area.

Each of the touch lines, the ground lines, the interface lines, the power lines, and the option control lines may be stacked on different layers with various interlayer insulating layers interposed therebetween. The low-resistance film may be disposed in front of the interface lines.

The low-resistance film may include an impedance control pattern area having in a shape of at least one opening or at least one cutout corresponding to the upper surface of the interface lines. The impedance control pattern area may overlap the interface lines and may be configured to adjust or maintain impedance sizes and electromagnetic interference magnitudes of the interface lines formed in the main plane area or the sub-extension area.

The circuit board may include a base substrate, a touch line layer disposed on the base substrate, including touch lines and at least one first interlayer insulating layer, a first ground line layer disposed on the touch line layer and including first ground lines and at least one second interlayer insulating layer, an interface line layer disposed on the first ground line layer and including interface lines and at least one third interlayer insulating layer, a second ground line layer disposed on the interface line layer and including second ground lines and at least one fourth interlayer insulating layer, and an option control line layer disposed on the second ground line layer and including option control lines and at least one fifth interlayer insulating layer.

The low-resistance film may be disposed in front of the interface lines and may correspond to the interface lines. The low-resistance film may include an impedance control pattern area having a shape of at least one opening or at least one cutout to correspond to the upper surface of the interface lines.

An electronic device includes a display device, an image signal processor configured to control an image display timing of the display device, a memory configured to store data and an application program for operating the display device, and a power module configured to provide a power signal to the display device. The display device includes a display panel including pixels disposed in a display area thereof, a touch driving circuit including a touch sensing unit disposed within the display panel, the touch sensing unit configured to generate touch coordinate data, a display driving circuit configured to supply a data voltage to the pixels of the display area and control an image display timing of the pixels, a circuit board that includes ouch lines, ground lines, interface lines, power lines, and option control lines, the circuit board being electrically connected to the display panel, and a low-resistance film disposed on an upper surface of the circuit board.

The circuit board may include a main plane area including an element arrangement area, an output pad area, and a line-embedded area, and a sub-extension area protruding and extending from the main plane area and including an input pad area including a plurality of input pads. The low-resistance film may at least partially cover a front surface of the line-embedded area and a front surface of the sub-extension area.

Each of the touch lines, the ground lines, the interface lines, the power lines, and the option control lines may be stacked on different layers with various interlayer insulating layers interposed therebetween. The low-resistance film may be disposed in front of the interface lines.

The circuit board may include a base substrate, a touch line layer disposed on the base substrate, including touch lines and at least one first interlayer insulating layer, a first ground line layer disposed on the touch line layer and including first ground lines and at least one second interlayer insulating layer, an interface line layer disposed on the first ground line layer and including interface lines and at least one third interlayer insulating layer, a second ground line layer disposed on the interface line layer and including second ground lines and at least one fourth interlayer insulating layer, and an option control line layer disposed on the second ground line layer and including option control lines and at least one fifth interlayer insulating layer.

The low-resistance film may include an impedance control pattern area having a shape of at least one opening or at least one cutout to correspond to the upper surface or the front direction of the interface lines. The impedance control pattern area may overlap the interface lines to adjust or maintain impedance sizes and electromagnetic interference magnitudes of the interface lines formed in the main plane area or the sub-extension area.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating a display device according to an embodiment;

FIG. 3 is a side view illustrating a display device according to an embodiment;

FIG. 4 is a schematic layout view illustrating an example of a display panel shown in FIGS. 1-3;

FIG. 5 is a schematic layout view illustrating an example of a touch sensing module shown in FIG. 3;

FIG. 6 is a detailed plan view illustrating a circuit board shown in FIGS. 1-3 according to an embodiment;

FIG. 7 is a cross-sectional view illustrating an example of a circuit board, taken along line I-I’ of FIG. 6;

FIG. 8 is a detailed plan view illustrating a circuit board shown in FIGS. 1-3 according to an embodiment;

FIG. 9 is a detailed plan view illustrating a circuit board shown in FIGS. 1-3 according to an embodiment;

FIG. 10 is a block diagram illustrating an electronic device including a display device according to an embodiment of the present disclosure; and

FIG. 11 illustrates schematic diagrams of electronic devices according to various embodiments.

### DETAILED DESCRIPTION

The present disclosure will now be described more fully hereinafter with reference to the accompanying drawings, in which embodiments of the disclosure are shown. This disclosure may, however, be embodied in different forms and should not necessarily be construed as limited to the embodiments set forth herein. Rather, these embodiments are provided so that this disclosure will be thorough and complete, and will filly convey the scope of the disclosure to those skilled in the art.

It will also be understood that when a layer is referred to as being "on" another layer or substrate, it can be directly on the other layer or substrate, or intervening layers may also be present. The same reference numbers may indicate the same components throughout the specification and the figures.

It will be understood that, although the terms “first,” “second,” etc. may be used herein to describe various elements, these elements should not necessarily be limited by these terms. These terms are used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Embodiments of the present disclosure relate to a display device and an electronic device architecture designed to increase image quality, touch sensitivity, and electromagnetic compatibility. The device may integrate a display panel with a built-in touch sensing unit, a display driving circuit, and a touch driving circuit, all connected through a specially engineered circuit board. The circuit board may carry various lines, for example, touch lines, power lines, interface lines, and control lines, while being overlaid with a low-resistance film. This film may be strategically placed on or near the interface lines to counter electromagnetic interference, which otherwise degrades signal integrity and causes image distortion.

According to this approach, the low-resistance film may have an impedance control pattern area, which can include openings or cutouts aligned with the interface lines. These structural variations allow fine control of line impedance and electromagnetic behavior, ensuring that video signals and touch data are transmitted consistently. This improves synchronization between the touch input and image output, enhances display clarity, and prevents signal delays that could disrupt user interactions. A multilayer circuit board design may also be used where different sets of lines, for example, ground, touch, and interface layers, are separated by insulating layers to further improve stability and reduce cross-talk.

Embodiments of the present disclosure may be intended to be widely applicable across consumer electronics, from smartphones and tablets to wearable devices, computer monitors, televisions, and even automotive displays. By stabilizing electrical characteristics and shielding against interference, the design may provide sharper visuals, faster response times, and greater reliability. Users may benefit from reduced distortion, more accurate touch detection, and overall higher satisfaction with display-based devices. The flexible implementation may allow use in both flat and curved panels, supporting modern trends like foldable displays and compact wearable screens.

Hereinafter, detailed embodiments will be described with reference to the accompanying drawings.

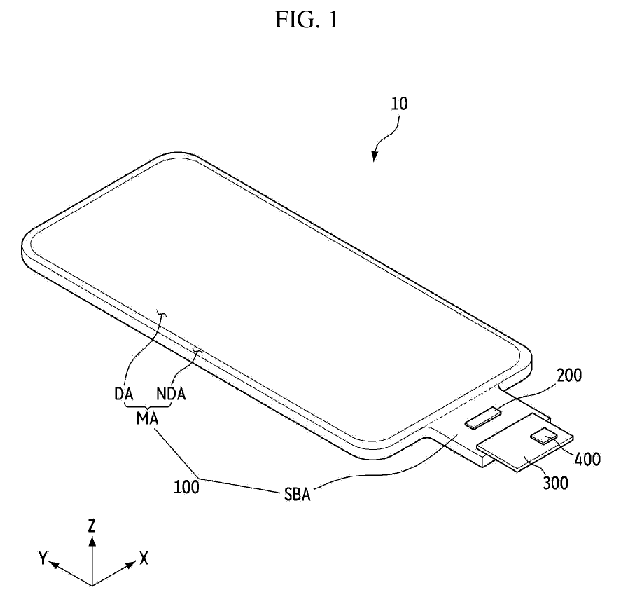

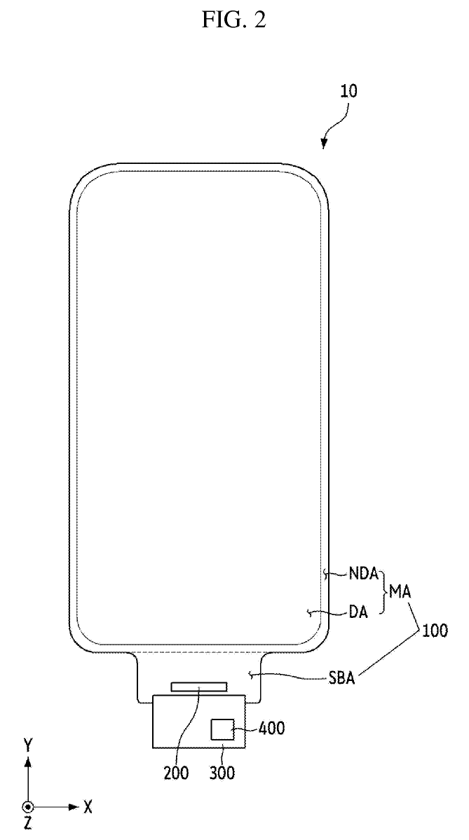

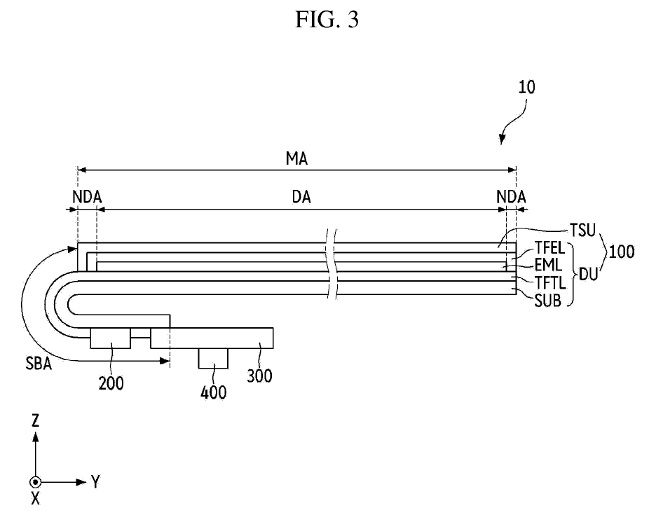

FIG. 1 is a perspective view illustrating a display device according to an embodiment. FIG. 2 is a plan view illustrating a display device according to an embodiment. FIG. 3 is a side view illustrating a display device according to an embodiment.

Referring to FIGS. 1-3, a display device 10, according to an embodiment, may be applied to a mobile electronic device such as a mobile phone, a smart phone, a tablet computer, a mobile communication terminal, an electronic diary, an electronic book, a portable multimedia player (PMP), a navigation device, and an ultra mobile personal computer (UMPC). Also, the display device 10, according to an embodiment, may be applied to a television, a laptop/notebook computer, a computer monitor, a digital signboard/billboard or an Internet of things (IoT) device as a display unit. Also, the display device 10, according to an embodiment, may be applied to a wearable device such as a smart watch, a watch phone, an eyeglasses-type display and a head mounted display (HMD). Also, the display device 10, according to an embodiment, may be applied to a dashboard of a vehicle, a center fascia of a vehicle, a center information display (CID) arranged in a dashboard of a vehicle, a room mirror display that replaces a side mirror of a vehicle or a display arranged on a rear surface of a front seat as an entertainment for a rear seat of a vehicle.

The display device 10, according to an embodiment, may be a light emitting display device such as an organic light emitting display device using an organic light emitting diode, a quantum dot light emitting display device including a quantum dot light emitting layer, an inorganic light emitting display device including an inorganic semiconductor, or a micro or nano light emitting display device using a micro or nano light emitting diode (micro LED or nano LED). The following description will be based on that the display device 10 is an organic light emitting display device, but the present disclosure is not necessarily limited thereto.

The display device 10, according to an embodiment, may include a display panel 100 in which a touch sensing unit TSU is formed, a display driving circuit 200, a circuit board 300 and a touch driving circuit 400.

The display panel 100 may be formed as a rectangular plane having a pair of short sides each extending in a first direction (e.g., an X-axis direction) and a pair of long sides each extending in a second direction (e.g., a Y-axis direction) crossing the first direction (e.g., the X-axis direction). A corner where the short sides extending in the first direction (e.g., the X-axis direction) and the long sides extending in the second direction (e.g., the Y-axis direction) meet may be rounded to have a curvature or formed at a right angle. A planar shape of the display panel 100 is not necessarily limited to a rectangular shape, and may be formed in another polygonal shape, a circular shape or an oval shape. The display panel 100 may be flat, but is not necessarily limited thereto. For example, the display panel 100 may include a curved portion formed at left and right ends, having a constant curvature or a variable curvature. In addition, the display panel 100 may be curved, twisted, bent, folded, or rolled.

The display panel 100 includes a main area MA and a sub-area SBA.

The main area MA includes a display area DA for displaying an image and a non-display area NDA that is a peripheral area of the display area DA. The display area DA includes pixels for displaying an image. The sub-area SBA may protrude from one side of the main area MA in the second direction (e.g., the Y-axis direction).

Although FIGS. 1 and 2 illustrate that the sub-area SBA is in an unfolded state, the sub-area SBA may be bent as shown in FIG. 3, and in this case, the sub-area SBA may be arranged on a lower surface of the display panel 100. When the sub-area SBA is bent, the sub-area SBA may overlap the main area MA in a third direction (e.g., a Z-axis direction), which is a thickness direction of a substrate SUB. The display driving circuit 200 may be arranged in the sub-area SBA.

As shown in FIG. 3, the display panel 100 includes a display module DU, which includes a substrate SUB, a thin film transistor layer TFTL, a light emitting element layer EML and an encapsulation layer TFEL, and a touch sensing unit TSU formed on a front surface (where a front surface or a front direction is a third directional surface or a third direction of Z-axis direction of a thickness direction) of the display module DU.

The thin film transistor layer TFTL may be arranged on the substrate SUB. The thin film transistor layer TFTL may be arranged in the main area MA and the sub-area SBA. The thin film transistor layer TFTL includes thin film transistors.

The light emitting element layer EML may be arranged on the thin film transistor layer TFTL. The light emitting element layer EML may be arranged in the display area DA of the main area MA. The light emitting element layer EML includes light emitting elements arranged in light emission areas.

The encapsulation layer TFEL may be arranged on the light emitting element layer EML. The encapsulation layer TFEL may be arranged in the display area DA and the non-display area NDA of the main area MA. The encapsulation layer TFEL includes at least one inorganic layer and at least one organic layer to encapsulate the light emitting element layer.

The touch sensing unit TSU may be formed on the encapsulation layer TFEL or packaged on the encapsulation layer TFEL. The touch sensing unit TSU may be formed on the display area DA of the main area MA. The touch sensing unit TSU may sense a touch of a person or an object by using touch electrodes.

At least one cover window for protecting an upper portion of the display panel 100 may be arranged on the touch sensing unit TSU. At least one cover window may be attached onto the touch sensing unit TSU by a transparent adhesive member such as an optically clear adhesive (OCA) film or an optically clear resin (OCR). The cover window may be an inorganic material such as glass or an organic material such as a plastic or polymer material. In order to prevent visibility of an image from being deteriorated due to reflection of external light, a polarizing layer may be additionally arranged between the touch sensing unit TSU and the cover window.

The display driving circuit 200 may generate signals and voltages for driving the display panel 100. The display driving circuit 200 may be formed as an integrated circuit (IC) and attached onto the display panel 100 in a chip on glass (COG) mode, a chip on plastic (COP) mode, or an ultrasonic bonding mode, but is not limited thereto. For example, the display driving circuit 20 may be attached onto the circuit board 300 in a chip on film (COF) mode.

The circuit board 30 may be a flexible printed circuit board, a printed circuit board, or a flexible film such as a chip on film.

The circuit board 300 may be attached to one end (e.g., an edge area) of the sub-area SBA formed in the display panel 100. The display panel 100 and the display driving circuit 200 may receive digital video data, timing signals, and driving voltages from a graphic system such as a graphic card or a graphic control processor through the circuit board 300. In this case, the timing signals may include vertical and horizontal synchronization signals, a data enable signal, a driving frequency clock signal, and the like. The driving voltages may include high-potential direct current voltages and low-potential ground voltages of various magnitudes such as about 5V to 21V, and an alternating current voltage of a preset magnitude.

The circuit board 300 includes a plurality of touch lines for transmitting a touch driving signal and a touch sensing signal, interface lines for transmitting digital video data and timing signals, power lines for transmitting driving voltages of different magnitudes, ground lines, and option control lines for transmitting offset control signals such as a sensor control signal or an image processing signal. The plurality of touch lines, at least one ground line, the interface lines, the power lines, and the option control lines may be arranged and configured to be stacked on different layers with each insulating layer interposed between the lines. The plurality of touch lines may include touch driving lines and touch sensing lines.

The touch driving circuit 400 may be arranged on the circuit board 300. The touch driving circuit 400 may be formed as an integrated circuit (IC) and packaged on the circuit board 300.

The touch driving circuit 400 is electrically connected to the touch electrodes of the touch sensing unit TSU through touch lines (e.g., touch driving lines and touch sensing lines) formed in the circuit board 300 and touch lines formed in the sub-area SBA. The touch driving circuit 400 applies touch driving signals to the touch electrodes of the touch sensing unit TSU and measures the amount of change in charges of mutual capacitance for the touch nodes formed by the touch electrodes. For example, the touch driving circuit 400 applies touch driving signals to the touch electrodes, and measures a change in mutual capacitance of touch nodes in accordance with a change in a voltage magnitude or the amount of current of the touch sensing signal received through the touch electrodes. In this way, the touch driving circuit 400 may determine whether there is a user’s touch or a user’s proximity, depending on the amount of change in charges of mutual capacitance of each of the touch nodes. The user’s touch may refer to an object such as a user’s finger or an electronic stylus/pen directly contacting one surface of the cover window arranged on the touch sensing unit TSU. The user’s proximity may refer to an object such as a user’s finger or an electronic stylus/pen being positioned above one surface of the cover window (e.g., hovering).

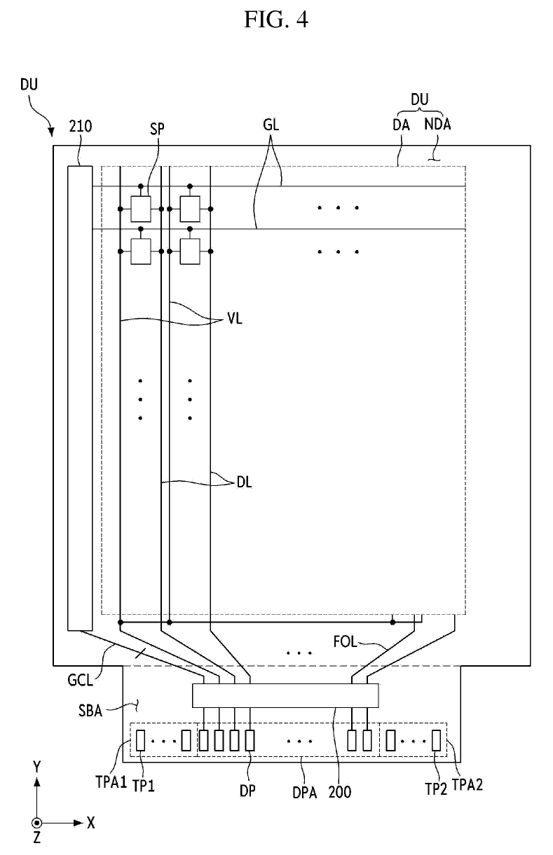

FIG. 4 is a schematic layout view illustrating an example of a display panel shown in FIGS. 1-3. For example, FIG. 4 is a layout view illustrating a display area DA and a non-display area NDA of the display module DU in a state before the touch sensing unit TSU is formed.

The display area DA is an area for displaying an image, and may be defined as a central area of the display panel 100. The display area DA may include a plurality of pixels SP, a plurality of gate lines GL, a plurality of data lines DL and a plurality of power lines VL. Each of the pixels SP may be defined as a minimum unit for outputting light.

The plurality of gate lines GL may supply a gate signal received from a gate driver 210 to the plurality of pixels SP. The plurality of gate lines GL may extend in the X-axis direction, and may be spaced apart from each other in the Y-axis direction crossing the X-axis direction.

The plurality of data lines DL may supply a data voltage received from the display driving circuit 200 to the plurality of pixels SP. The plurality of data lines DL may extend in the Y-axis direction, and may be spaced apart from each other in the X-axis direction.

The plurality of power lines VL may supply a power voltage received from the display driving circuit 200 to the plurality of pixels SP. The power voltage may be at least one of a driving voltage, an initialization voltage, or a reference voltage. The plurality of power lines VL may extend in the Y-axis direction, and may be spaced apart from each other in the X-axis direction.

The non-display area NDA may surround the display area DA. The non-display area NDA may include a gate driver 210, fan-out lines FOL, and gate control lines GCL. The gate driver 210 may generate a plurality of gate signals based on a gate control signal and sequentially supply the plurality of gate signals to the plurality of gate lines GL in accordance with a set order.

The fan-out lines FOL may extend from the display driving circuit 200 to the display area DA. The fan-out lines FOL may supply the data voltage received from the display driving circuit 200 to the plurality of data lines DL.

The gate control line GCL may extend from the display driving circuit 200 to the gate driver 210. The gate control line GCL may supply the gate control signal received from the display driving circuit 200 to the gate driver 210.

The sub-area SBA may include a display driving circuit 200, a display pad area DPA, and first and second touch pad areas TPA1 and TPA2.

The display driving circuit 200 may output signals and voltages for driving the display panel 100 to the fan-out lines FOL. The display driving circuit 200 may supply the data voltage to the data line DL through the fan-out lines FOL. The data voltage may be supplied to the plurality of pixels SP, and may determine luminance of the plurality of pixels SP. The display driving circuit 200 may supply the gate control signal to the gate driver 210 through the gate control line GCL.

The display pad area DPA, the first touch pad area TPA1, and the second touch pad area TPA2 may be arranged at an edge of the sub area SBA. The display pad area DPA, the first touch pad area TPA1, and the second touch pad area TPA2 may be electrically connected to the circuit board 300 by using an anisotropic conductive film or a low-resistance and high reliability material such as SAP.

The display pad area DPA may include a plurality of display pad portions. The plurality of display pad portions may be connected to the display driving circuit 200 through the circuit board 300. The plurality of display pad portions may be connected to the circuit board 300 to receive digital video data, and may supply the digital video data to the display driving circuit 200.

Thus, a versatile display device can be used in many applications, including mobile devices, televisions, computer monitors, wearables, and vehicle displays. The device features a display panel with a main area for image display and a sub-area that can be bent or folded to house driving circuits, along with layers such as a thin film transistor layer, a light-emitting layer, an encapsulation layer, and a touch sensing unit. The panel connects to a circuit board carrying multiple lines (e.g., touch, data, power, and control), which interface with display and touch driving circuits to deliver video signals, manage timing, detect user touches or proximity, and ensure accurate image output.

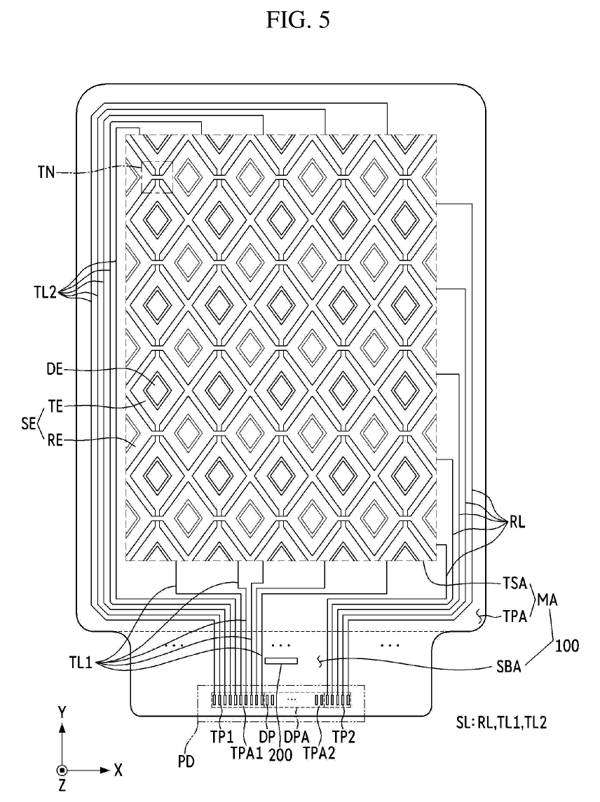

FIG. 5 is a schematic layout view illustrating an example of a touch sensing module shown in FIG. 3.

In FIG. 5, only driving electrodes TE, sensing electrodes RE, dummy patterns DE, touch lines SL, and first and second touch pads TP1 and TP2 are shown for convenience of description.

In FIG. 5, the touch electrodes SE of the main area MA include two types of electrodes, for example, driving electrodes TE and sensing electrodes RE, and are driven in a mutual capacitance manner in which the amount of change in charges of mutual capacitance of each of a plurality of touch nodes is sensed through the sensing electrodes RE after a touch driving signal is applied to the driving electrodes TE, but the present disclosure is not necessarily limited thereto.

The main area MA of the touch sensing unit TSU includes a touch sensing area TSA for sensing a user’s touch and a touch peripheral area TPA arranged around the touch sensing area TSA. The touch sensing area TSA may overlap the display area DA of FIGS. 1-3, and the touch peripheral area TPA may overlap the non-display area NDA.

The driving electrodes TE, the sensing electrodes RE, and the dummy patterns DE are arranged in the touch sensing area TSA. The driving electrodes TE and the sensing electrodes RE may be electrodes for forming mutual capacitance to sense a touch of an object or a person.

The sensing electrodes RE may be arranged in parallel in the first direction (e.g., the X-axis direction) and the second direction (e.g., the Y-axis direction). The sensing electrodes RE may be electrically connected to each other in the first direction (e.g., the X-axis direction). The sensing electrodes RE adjacent to each other in the first direction (e.g., the X-axis direction) may be connected to each other. The sensing electrodes RE adjacent to each other in the second direction (e.g., the Y-axis direction) may be electrically separated from each other. Accordingly, a touch node TN, in which mutual capacitance is formed, may be arranged in each of intersections of the driving electrodes TE and the sensing electrodes RE. The plurality of touch nodes TN may correspond to the intersections of the driving electrodes TE and the sensing electrodes RE.

The driving electrodes TE may be arranged in parallel in the first direction (e.g., the X-axis direction) and the second direction (e.g., the Y-axis direction). The driving electrodes TE adjacent to each other in the first direction (e.g., the X-axis direction) may be electrically separated from each other. The driving electrodes TE may be electrically connected to each other in the second direction (e.g., the Y-axis direction). The driving electrodes TE adjacent to each other in the second direction (e.g., the Y-axis direction) may be connected to each other through a separate connection electrode.

Each of the dummy patterns DE may be arranged to be surrounded by the driving electrode TE or the sensing electrode RE. Each of the dummy patterns DE may be electrically separated from the driving electrode TE or the sensing electrode RE. Each of the dummy patterns DE may be arranged to be spaced apart from the driving electrode TE or the sensing electrode RE. Each of the dummy patterns DE may be electrically floated.

In FIG. 5, each of the driving electrodes TE, the sensing electrodes RE, and the dummy patterns DE has a rhombus planar shape, but is not necessarily limited thereto. For example, each of the driving electrodes TE, the sensing electrodes RE, and the dummy pattern DE may have a planar shape such as a rectangular shape other than a rhombus shape, another polygonal shape other than the rectangular shape, a circular shape or an oval shape.

The touch lines SL may be arranged in the sensor peripheral area TPA. The touch lines SL include first and second touch driving lines TL1 and TL2 connected to the driving electrodes TE, and touch sensing lines RL connected to the sensing electrodes RE.

Each of the sensing electrodes RE arranged at one end of the touch sensing area TSA may be connected to the touch sensing lines RL on a one-to-one basis. For example, among the sensing electrodes RE electrically connected in the first direction (e.g., the X-axis direction) as shown in FIG. 5, each of the sensing electrodes RE arranged at the right end may be connected to each of the touch sensing lines RL. Each of the touch sensing lines RL may be connected to the second touch pads TP2 arranged on the pad portion PD on a one-to-one basis.

The driving electrodes TE arranged at one end of the touch sensing area TSA may be connected to the first touch driving lines TL1 on a one-to-one basis, and the driving electrodes TE arranged at the other end of the touch sensing area TSA may be connected to the second touch driving lines TL2 on a one-to-one basis. For example, among the driving electrodes TE electrically connected in the second direction (e.g., the Y-axis direction), the driving electrodes TE arranged at the end of a first side (e.g., a direction adjacent to the display pad area DPA) may be connected to the first touch driving line TL1, respectively, and the driving electrodes TE arranged at the end of a second side (e.g., a direction opposite to the display pad area DPA) may be connected to the second touch driving line TL2, respectively. The second touch driving lines TL2 may be connected to the driving electrodes TE at a second side (e.g., a direction opposite to the display pad area DPA) of the touch sensing area TSA by passing through the outside of a left or right direction of the touch sensing area TSA.

The first touch driving lines TL1 and the second touch driving lines TL2 may be connected to the first touch pads TP1 arranged on the pad portion PD on a one-to-one basis. The driving electrodes TE are connected to the first and second touch driving lines TL1 and TL2 at respective sides of the touch sensing area TSA to receive the touch driving signal. Therefore, a difference between the touch driving signal applied to the driving electrodes TE arranged at the first side (e.g., the direction adjacent to the display pad area DPA) of the touch sensing area TSA and the touch driving signal applied to the driving electrodes TE arranged at the second side (e.g., the direction opposite to the display pad area DPA) of the touch sensing area TSA may be prevented from occurring due to RC delay of the touch driving signal.

When the circuit board 300 is connected to the sub-area SBA of the display panel 100, the display pad area DPA of the pad portion PD and the first and second touch pad areas TPA1 and TPA2 may correspond to pads of the display panel 100 connected to the circuit board 300. Therefore, the pads of the display panel 100 may be in contact with the display pads DP, the first touch pads TP1, and the second touch pad TP2. The display pads DP, the first touch pads TP1, and the second touch pad TP2 may be electrically connected to the pads of the circuit board 300 by using an anisotropic conductive film or a low-resistance and high reliability material such as SAP. As a result, the display pads DP, the first touch pads TP1, and the second touch pads TP2 may be electrically connected to the touch driving circuit 400 arranged on the circuit board 300.

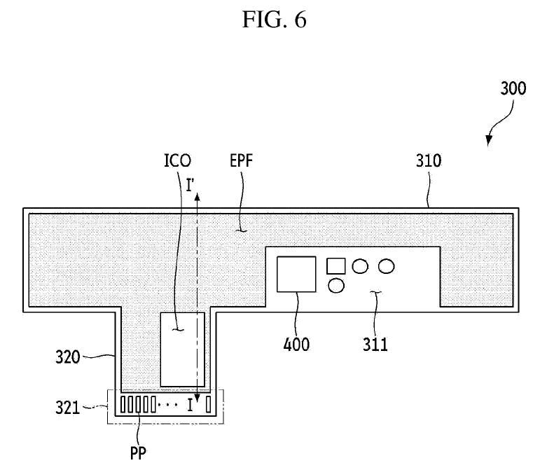

FIG. 6 is a detailed plan view illustrating a circuit board shown in FIGS. 1-3 according to an embodiment.

Referring to FIG. 6, the circuit board 300 is classified into a main plane area 310 and a sub-extension area 320. The circuit board 300 includes a low-resistance film EPF adhered by at least partially covering a front surface (e.g., where the front surface or the front direction is a surface of Z-axis direction or the Z-axis direction, which is the thickness direction) of a line-embedded area and a front surface (e.g., the third direction) of the sub-extension area 320.

For example, the main plane area 310 includes an element arrangement area 311, an output pad area, and a line-embedded area, and the sub-extension area 320 protrudes and extends from the main plane area 310, and includes an input pad area 321 arranged at one end.

The low-resistance film EPF is adhered by at least partially covering the front surface of the line-embedded area and the front surface (e.g., the third direction) of the sub-extension area 320.

The main plane area 310 is formed in a polygonal plane shape such as a circle, a rhombus, and a rectangle, and a plurality of output pad portions may be formed and arranged on any one side of the main plane area 310. An element arrangement area 311 is defined in any one outer plane area of the main plane area 310, and the integrated circuit such as the touch driving circuit 400 and various electrical elements such as a resistance element and a capacitance may be arranged in the element arrangement area 311.

A plurality of touch lines for transmitting first and second touch driving signals and touch sensing signals, interface lines for transmitting digital video data and timing signals, power lines for transmitting driving voltages of different magnitudes, ground lines, and option control lines for transmitting offset control signals such as a sensor control signal and an image processing signal are patterned and arranged in the line-embedded area of the main plane area 310. As described above, the plurality of touch lines, at least one ground line, the interface lines, the power lines, and the option control lines may be arranged and configured in a shape stacked on different layers with each insulating layer interposed between these lines.

The sub-extension area 320 is formed integrally with the main plane area 310, and extends to the input pad area 321 at one end as a shape protrudes to any one side of the main plane area 310. An input pad portion is formed in the input pad area 321, and input pads PP of the input pad portion are electrically connected to contact pads such as a graphic system, such as a graphic card, or a graphic control processor.

The sub-extension area 320 is formed in a quadrangular shape such as a rectangle or square, and the interface lines, the power lines, and the option control lines, which are formed in the line-embedded area of the main plane area 310, extend to the sub-extension area 320.

The interface lines, the power lines, the option control lines, etc., which are formed in the line-embedded area of the main plane area 310, may have one end that is in contact with output pads of the output pad portion on a one-to-one basis, and the other end that extends to the sub-extension area 320 and is in contact with the input pads PP of the input pad portion formed in the input pad area 321 of the sub-extension area 320 on a one-to-one basis.

For example, the touch lines formed in the line-embedded area of the circuit board 300 transmit the first and second touch driving signals output from a touch driving signal output terminal of the touch driving circuit 400 to the output pads arranged on the output pad portion, and on the contrary, transmit the touch sensing signals input through the input pads of the output pad portion to the touch driving circuit 400.

In addition, the interface lines of the circuit board 300 transmit digital video data and timing signals, which are input through the input pads PP arranged in the input pad portion at one end, to the output pads arranged in the output pad portion at the other end. The digital video data and the timing signals may be supplied to the display driving circuit 200 of the sub-area SBA through the output pads.

The ground lines of the circuit board 300 transmit a ground voltage input through the input pads arranged in the input pad portion to the output pads arranged in the output pad portion at the other end. The ground voltage is supplied to a ground terminal of the display driving circuit 200 packaged in the sub-area SBA.

The option control lines of the circuit board 300 transmit offset control signals such as a sensor control signal or an image processing signal, which is input through the input pads arranged in the input pad portion, to the output pads arranged in the other output pad portion at the other end. The offset control signals such as a sensor control signal or an image processing signal are supplied to the display driving circuit 200 through the output pad or the like.

The low-resistance film EPF is adhered by covering the front surface (e.g., the third direction (e.g., the Z-axis direction)) or at least a partial area of the main plane area 310 and the sub-extension area 320 except for the element arrangement area 311 of the main plane area 310. The low-resistance film EPF may include a non-conductive film or a thin film forming material such as rubber made of an elastic material, a non-conductive ceramic compound, an insulating plastic film, and an insulating tape.

The low-resistance film EPF includes an impedance control pattern area ICO formed to include at least one opening (e.g., open area) or at least one cutout in a front direction (e.g., the third direction (e.g., the Z-axis direction)) of the interface lines to correspond to the interface lines formed in the main plane area 310 and the sub-extension area 320.

The impedance control pattern area ICO of the low-resistance film EPF may be formed in any one area of the front direction of the main plane area 310 or the sub-extension area 320, and may be arranged in any one area of the front surface (e.g., the third direction (e.g., the Z-axis direction)) that overlaps the interface lines to adjust or maintain an impedance size of the interface lines.

As described above, the interface lines, the power lines, and the option control lines are respectively patterned and arranged on inner layers of any one of the main plane area 310 and the sub-extension area 320, so that their one ends are in contact with the output pads of the main plane area 310 on a one-to-one basis and their other ends are in contact with the input pads PP of the sub-extension area 320 on a one-to-one basis.

The low-resistance film EPF may be arranged by covering the line-embedded area and the main plane area 310 and the front surface of the sub-extension area 320, in which the interface lines, the power lines, and the option control lines are formed.

However, the impedance control pattern area ICO of the low-resistance film EPF may be arranged in the front direction (e.g., the third direction (e.g., the Z-axis direction) that overlaps the interface lines in a state that it includes at least one opening or at least one open cutout, thereby adjusting an electromagnetic interference magnitude of the interface lines and adjusting or maintaining the impedance size.

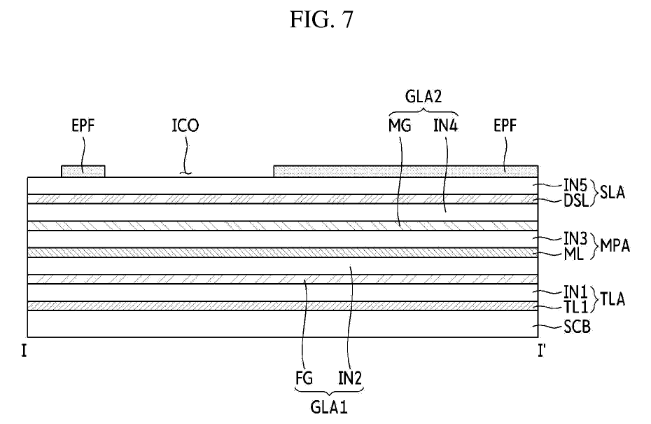

FIG. 7 is a cross-sectional view illustrating an example of a circuit board, taken along line I-I’ of FIG. 6.

Referring to FIG. 7, the circuit board 300 may include a plurality of line layers stacked and arranged on different layers on a base substrate SCB with each insulating layer interposed between the line layers.

For example, the circuit board 300 may include a base substrate SCB, a touch line layer TLA, a first ground line layer GLA1, an interface line layer MPA, a second ground line layer GLA2, and an option control line layer SLA.

For example, the base substrate SCB may be formed as an insulating substrate such as glass, silicon and plastic.

The touch line layer TLA is patterned and formed on the base substrate SCB to include touch lines (e.g., first touch driving lines TL1) and at least one first interlayer insulating layer IN1.

The first ground line layer GLA1 is patterned and formed on the touch line layer TLA to include first ground lines FG and at least one second interlayer insulating layer IN2.

The interface line layer MPA is patterned and formed on the first ground line layer GLA1 to include interface lines ML and at least one third interlayer insulating layer IN3.

The second ground line layer GLA2 is patterned and formed on the interface line layer MPA to include second ground lines MG and at least one fourth interlayer insulating layer IN4.

The option control line layer SLA is patterned and formed on the second ground line layer GLA2 to include option control lines DSL and at least one fifth interlayer insulating layer IN5.

A low-resistance film EPF, in which an impedance control pattern area ICO is formed in a front direction (e.g., the third direction (e.g., the Z-axis direction)) of at least a portion of the interface lines ML, is attached to and arranged on the option control line layer SLA. At least one opening or at least one open cutout is formed in the impedance control pattern area ICO of the low-resistance film EPF, so that electromagnetic field characteristics of the interface lines ML may be uniformly maintained or adjusted so as not to be distorted. Accordingly, the impedance sizes of the interface lines ML may be efficiently adjusted or uniformly maintained.

Referring to FIG. 7, the base substrate SCB may be made of an insulating material such as a polymer resin. For example, the base substrate SCB may be made of polyimide. The base substrate SCB may be a flexible substrate capable of being subjected to bending, folding, rolling, or the like. A barrier layer may be first formed on the base substrate SCB. The barrier layer is a film for protecting each of the interlayer insulating layers IN1 to IN5 and each line such as the interface line ML from moisture permeated through the base substrate SCB vulnerable to moisture permeation. The barrier layer may include a multi-layer in which a silicon nitride layer, a silicon oxynitride layer, and a silicon oxide layer are stacked.

The touch lines (e.g., the first touch driving lines TL1) of the touch line layer TLA may be formed as a single layer or multi-layer made of any one of molybdenum (Mo), aluminum (Al), chromium (Cr), gold (Au), titanium (Ti), nickel (Ni), neodymium (Nd), and copper (Cu), or their alloy. The first interlayer insulating layer IN1 may include an inorganic layer, for example, a silicon nitride layer, a silicon oxynitride layer, a silicon oxide layer, a titanium oxide layer, or an aluminum oxide layer.

The first ground line FG of the first ground line layer GLA1 may be formed in a through-ground line shape, that is, a flat panel line shape. The first ground line FG may be formed as a single layer or multi-layer made of any one of molybdenum (Mo), aluminum (Al), chromium (Cr), gold (Au), titanium (Ti), nickel (Ni), neodymium (Nd), and copper (Cu), or their alloy. The second interlayer insulating layer IN2 may include the same inorganic material as that of the first interlayer insulating layer IN1, for example, a silicon nitride layer, a silicon oxynitride layer, a silicon oxide layer, a titanium oxide layer, or an aluminum oxide layer.

The interface lines ML of the interface line layer MPA may be formed as a single layer or multi-layer made of the same metal material as that of the touch lines (e.g., the first touch driving lines TL1) or their alloy. The third interlayer insulating layer IN3 may include the same inorganic material as that of the first or second interlayer insulating layer IN1 or IN2.

The second ground lines MG of the second ground line layer GLA2 may be patterned and formed in a line shape having a mesh structure or a net structure. The second ground lines MG may be formed as a single layer or multi-layer made of the same metal material as that of the first ground line FG or their alloy. The fourth interlayer insulating layer IN3 may include the same inorganic material as that of the first or second interlayer insulating layer IN1 or IN2.

The option control lines DSL of the option control line layer SLA may be formed as a single layer or multiple layers consisting of the same metal material as that of the touch lines (e.g., the first touch driving lines TL1) or their alloy. The fifth interlayer insulating layer IN5 may include the same inorganic material as that of the first or second interlayer insulating layer IN1 or IN2.

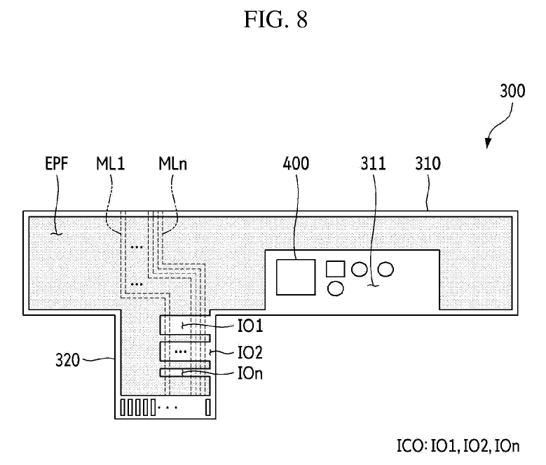

FIG. 8 is a detailed plan view illustrating a circuit board shown in FIGS. 1-3 according to an embodiment.

Referring to FIG. 8, the low-resistance film EPF is adhered by covering the front surface (e.g., the third direction (e.g., the Z-axis direction) or at least a portion of the main plane area 310 and the sub-extension area 320 except for the element arrangement area 311 of the main plane area 310.

The low-resistance film EPF includes an impedance control pattern area ICO formed to open areas of front surfaces (e.g., the third direction (e.g., the Z-axis direction)) of at least some corresponding to the interface lines formed in the main plane area 310 and the sub-extension area 320, for example, first to (n)th interface lines ML1 to MLn. In this case, ‘n’ is a positive integer.

The impedance control pattern area ICO adjusts impedance sizes of the interface lines ML1 to MLn in accordance with a size or area of the open area such as an opening or a cutout.

For example, the impedance control pattern area ICO includes first to (n)th cutouts IO1 to IOn that are cut to have the same size and area as or different sizes and areas so that the areas of the front surfaces of at least some corresponding to the interface lines ML1 to MLn are opened. For example, the first and second cutouts IO1 and IO2 are cut to have the same size and area, and the (n)th cutout portion IOn may be cut to have different sizes and areas from those of the first and second cutouts IO1 and IO2.

In addition, the open cutout shapes of the first to (n)th cutouts IO1 to IOn may be formed in a polygonal shape such as a triangle or a rhombus in addition to a quadrangle shown in the drawing, or may be formed in the same or different shapes such as a circle, a semicircle, or an oval.

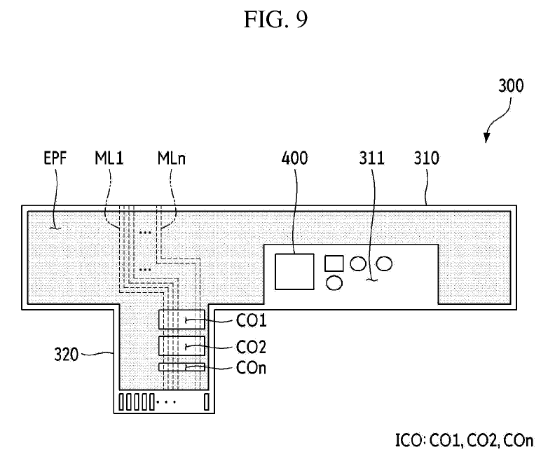

FIG. 9 is a detailed plan view illustrating a circuit board shown in FIGS. 1-3 according to an embodiment.

Referring to FIG. 9, the low-resistance film EPF includes an impedance control pattern area ICO formed to open areas of front surfaces of at least some corresponding to the interface lines formed in the main plane area 310 and the sub-extension area 320, for example, first to (n)th interface lines ML1 to MLn, thereby adjusting impedance sizes of the interface lines ML1 to MLn in accordance with the size or area of the open areas.

The impedance control pattern area ICO includes first to (n)th openings CO1 to COn formed so that areas of front surfaces of at least some corresponding to the interface lines ML1 to MLn are opened to have the same size and area or different sizes or areas. For example, the first and second openings CO1 and CO2 are opened to have the same size and area, and the (n)th opening COn may be opened to have different sizes and areas from those of the first and second openings CO1 and CO2.

In addition, the open shapes of the first to (n)th openings CO1 to COn may be formed in a polygonal shape such as a triangle or a rhombus in addition to a quadrangle shown in the drawing, or may be formed in the same or different shapes such as a circle, a semicircle, or an oval.

The display device 10, according to an embodiment of the present disclosure, may be applied to various electronic devices. The electronic device according to one embodiment includes the display device 10 according to an embodiment of the present disclosure, and may further include a module or device having other additional functions in addition to the display device.

Thus, the touch sensing module may driving electrodes, sensing electrodes, and dummy patterns arranged in a grid of touch nodes that detect changes in mutual capacitance when touched or approached. These electrodes connect through touch lines and pads to the touch driving circuit, which ensures balanced signal delivery and accurate touch detection without delay. The circuit board integrates multiple signal lines in stacked layers and is covered by a low-resistance film with impedance control patterns (e.g., cutouts or openings) positioned over the interface lines, allowing electromagnetic interference reduction and stable impedance for reliable display performance.

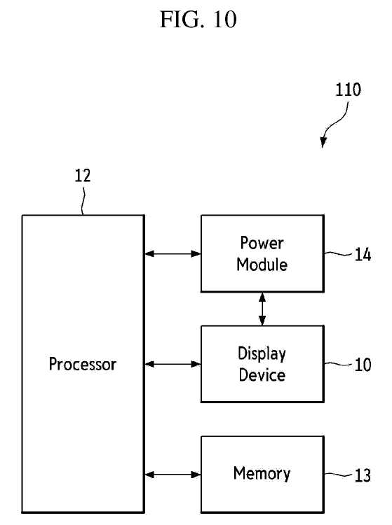

FIG. 10 is a block diagram illustrating an electronic device according to one embodiment.

Referring to FIG. 10, an electronic device 110, according to an embodiment, may include a display device 10, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information required for an operation of the processor 12 or the display device 10 may be stored in the memory 13. When the processor 12 executes an application stored in the memory 13, an image data signal and/or an input control signal is transmitted to the display device 10, and the display device 10 may process the received signal and output image information through a display screen.

The power module 14 may include a power supply module such as a power adapter or a battery device, and a power conversion module converting a power source supplied by the power supply module to generate a power source required for the operation of the electronic device 110.

At least one of the respective components of the above-described electronic device 110 may be included in the display device according to the above-described embodiments. Also, some of the individual modules functionally included in one module may be included in the display device 10, and others thereof may be provided separately from the display device 10. For example, the display device 10 includes a display panel, and the processor 12, the memory 13 and the power module 14 may be provided as other devices in the electronic device 110 that are not the display device 10.

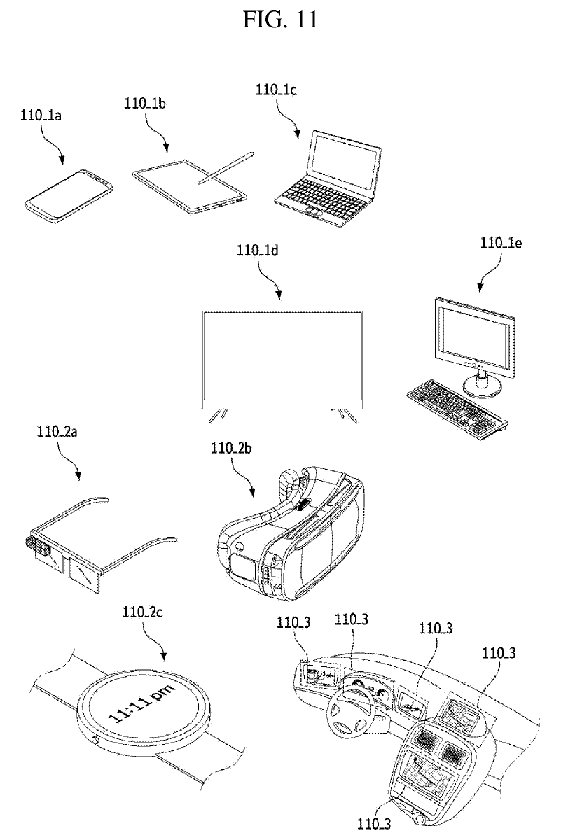

FIG. 11 illustrates schematic diagrams of electronic devices according to various embodiments.

Referring to FIG. 11, various electronic devices 110 to which the display devices 10 according to embodiments are applied may include not only electronic devices for image display, such as a smart phone 110_1a, a tablet computer 110_1b, a laptop/notebook computer 110_1c, a TV 110_1d, and a computer monitor 110_1e, but also wearable electronic devices including display modules such as smart glasses 110_2a, a head mounted display 110_2b, and a smart watch 110_2c, and a vehicle electronic device 110_3 including display modules such as a vehicle dashboard, a center fascia, a center information display (CID) arranged on the dashboard, and a room mirror display. In addition, the display device 10 may be applied as a display member of a television, a laptop/notebook computer, a computer monitor, a digital advertising board/billboard, or an Internet of Things (IOT) device.

In concluding the detailed description, those skilled in the art will appreciate that many variations and modifications can be made to the embodiments without substantially departing from the principles of the present disclosure.

What is claimed is:

1. A display device, comprising:
a display panel including a plurality of pixels disposed within a display area of the display panel;
a touch driving circuit including a touch sensing unit disposed within the display panel, the touch sensing unit configured to generate touch coordinate data;
a display driving circuit configured to supply a data voltage to the plurality of pixels of the display area and control an image display timing of the plurality of pixels;
a circuit board that includes touch lines, ground lines, interface lines, power lines, and option control lines, the circuit board being electrically connected to the display panel; and
a low-resistance film disposed on an upper surface of the circuit board,
wherein the low-resistance film is disposed on an upper surface of the interface lines.

2. The display device of claim 1, wherein each of the touch lines, the ground lines, the interface lines, the power lines, and the option control lines is stacked in a plurality of layers with interlayer insulating layers interposed therebetween, and
wherein the low-resistance film is disposed on the upper surface of the interface lines, and includes an impedance control pattern area having a shape of at least one opening or at least one cutout.

3. The display device of claim 2, wherein the low-resistance film includes a rubber material, a non-conductive film including a non-conductive ceramic compound, an insulating tape including a non-conductive thin film forming material, or an insulating plastic film.

4. The display device of claim 1, wherein the circuit board includes:
a main plane area including an element arrangement area, an output pad area, and a line-embedded area; and
a sub-extension area protruding and extending from the main plane area and including an input pad area including a plurality of input pads,
wherein the low-resistance film at least partially covers a front surface of the line-embedded area and a front surface of the sub-extension area.

5. The display device of claim 4, wherein each of the touch lines, the ground lines, the interface lines, the power lines, and the option control lines are stacked on different layers with various interlayer insulating layers interposed therebetween, and
wherein the low-resistance film is disposed in front of the interface lines.

6. The display device of claim 5, wherein the low-resistance film includes an impedance control pattern area having a shape of at least one opening or at least one cutout corresponding to the upper surface of the interface lines, and
wherein the impedance control pattern area overlaps the interface lines and is configured to adjust or maintain impedance sizes and electromagnetic interference magnitudes of the interface lines formed in the main plane area or the sub-extension area.

7. The display device of claim 4, wherein the circuit board includes:
a base substrate;
a touch line layer disposed on the base substrate, including touch lines and at least one first interlayer insulating layer;
a first ground line layer disposed on the touch line layer and including first ground lines and at least one second interlayer insulating layer;
an interface line layer disposed on the first ground line layer and including interface lines and at least one third interlayer insulating layer;
a second ground line layer disposed on the interface line layer and including second ground lines and at least one fourth interlayer insulating layer; and
an option control line layer disposed on the second ground line layer and including option control lines and at least one fifth interlayer insulating layer.

8. The display device of claim 7, wherein the low-resistance film is disposed in front of the interface lines and corresponds to the interface lines, and
wherein the low-resistance film includes an impedance control pattern area having a shape of at least one opening or at least one cutout to correspond to the upper surface of the interface lines.

9. A display device, comprising
a display panel including pixels disposed in a display area thereof;
a touch driving circuit including a touch sensing unit disposed within the display panel, the touch sensing unit configured to generate touch coordinate data;
a display driving circuit configured to supply a data voltage to the pixels of the display area and control an image display timing of the plurality of pixels; and
a circuit board that includes touch lines, ground lines, interface lines, power lines, and option control lines, the circuit board being electrically connected to the display panel,
wherein the circuit board includes a low-resistance film disposed on an upper surface of the circuit board, and
wherein the low-resistance film is arranged on an upper surface of the interface lines.

10. The display device of claim 9, wherein the low-resistance film includes a rubber, a non-conductive film including a non-conductive ceramic compound, an insulating tape including a non-conductive thin film forming material, or an insulating plastic film.

11. The display device of claim 9, wherein the circuit board includes:
a main plane area including an element arrangement area, an output pad area, and a line-embedded area; and
a sub-extension area protruding and extending from the main plane area and including an input pad area including a plurality of input pads,
wherein the low-resistance film at least partially covers a front surface of the line-embedded area and a front surface of the sub-extension area.

12. The display device of claim 11, wherein each of the touch lines, the ground lines, the interface lines, the power lines, and the option control lines are stacked on different layers with various interlayer insulating layers interposed therebetween, and
wherein the low-resistance film is disposed in front of the interface lines.

13. The display device of claim 12, wherein the low-resistance film includes an impedance control pattern area having in a shape of at least one opening or at least one cutout corresponding to the upper surface of the interface lines, and
wherein the impedance control pattern area overlaps the interface lines and is configured to adjust or maintain impedance sizes and electromagnetic interference magnitudes of the interface lines formed in the main plane area or the sub-extension area.

14. The display device of claim 11, wherein the circuit board includes:
a base substrate;
a touch line layer disposed on the base substrate, including touch lines and at least one first interlayer insulating layer;
a first ground line layer disposed on the touch line layer and including first ground lines and at least one second interlayer insulating layer;
an interface line layer disposed on the first ground line layer and including interface lines and at least one third interlayer insulating layer;
a second ground line layer disposed on the interface line layer and including second ground lines and at least one fourth interlayer insulating layer; and
an option control line layer disposed on the second ground line layer and including option control lines and at least one fifth interlayer insulating layer.

15. The display device of claim 14, wherein the low-resistance film is disposed in front of the interface lines and corresponds to the interface lines, and
wherein the low-resistance film includes an impedance control pattern area having a shape of at least one opening or at least one cutout to correspond to the upper surface of the interface lines.

16. An electronic device, comprising
a display device;
an image signal processor configured to control an image display timing of the display device;
a memory configured to store data and an application program for operating the display device; and
a power module configured to provide a power signal to the display device,
wherein the display device includes:
a display panel including pixels disposed in a display area thereof;
a touch driving circuit including a touch sensing unit disposed within the display panel, the touch sensing unit configured to generate touch coordinate data;
a display driving circuit configured to supply a data voltage to the pixels of the display area and control an image display timing of the pixels;
a circuit board that includes touch lines, ground lines, interface lines, power lines, and option control lines, the circuit board being electrically connected to the display panel; and
a low-resistance film disposed on an upper surface of the circuit board.

17. The electronic device of claim 16, wherein the circuit board includes:
a main plane area including an element arrangement area, an output pad area, and a line-embedded area; and
a sub-extension area protruding and extending from the main plane area and including an input pad area including a plurality of input pads,
wherein the low-resistance film at least partially covers a front surface of the line-embedded area and a front surface of the sub-extension area.

18. The electronic device of claim 17, wherein each of the touch lines, the ground lines, the interface lines, the power lines, and the option control lines are stacked on different layers with various interlayer insulating layers interposed therebetween, and
wherein the low-resistance film is disposed in front of the interface lines.

19. The electronic device of claim 17, wherein the circuit board includes:
a base substrate;
a touch line layer disposed on the base substrate, including touch lines and at least one first interlayer insulating layer;
a first ground line layer disposed on the touch line layer and including first ground lines and at least one second interlayer insulating layer;
an interface line layer disposed on the first ground line layer and including interface lines and at least one third interlayer insulating layer;
a second ground line layer disposed on the interface line layer and including second ground lines and at least one fourth interlayer insulating layer; and
an option control line layer disposed on the second ground line layer and including option control lines and at least one fifth interlayer insulating layer.

20. The electronic device of claim 19, wherein the low-resistance film includes an impedance control pattern area having a shape of at least one opening or at least one cutout to correspond to the upper surface of the interface lines, and
wherein the impedance control pattern area overlaps the interface lines to adjust or maintain impedance sizes and electromagnetic interference magnitudes of the interface lines formed in the main plane area or the sub-extension area.
